(19) United States
(12) Patent Application Publication
(10) Pub. No.: US 2017/0317587 A1
(43) Pub. Date: Nov. 2, 2017

(54) SWITCHING REGULATOR WITH IMPROVED EFFICIENCY AND METHOD THEREOF

(71) Applicant: Chengdu Monolithic Power Systems Co., Ltd., Chengdu (CN)

(72) Inventors: Xudong Zhang, Chengdu (CN); Yike Li, Chengdu (CN)

(21) Appl. No.: 15/488,389

(22) Filed: Apr. 14, 2017

(30) Foreign Application Priority Data
Apr. 28, 2016 (CN) 201610273944.5

(51) Int. Cl. H02M 3/156; G01R 19/165; G01R 19/00; H04W 76/04; G01R 19/30

(52) U.S. Cl. CPC H02M 3/156; H04W 76/048; G01R 19/30; G01R 19/003; G01R 19/16557; G01R 19/16585

(57) ABSTRACT

A switching regulator with constant on time control adopts a timer to time when the system is in discontinuous current mode (DCM). If the DCM lasted for a set time, a power stage in the switching regulator is controlled to be ON for a minimum on time duration, so as to ensure the switching regulator enters sleep mode.

### CROSS-REFERENCE TO RELATED APPLICATIONS

This application claims priority to and the benefit of Chinese Patent Application No. 201610273944.5, filed Apr. 28, 2016, which is incorporated herein by reference in its entirety.

### FIELD

The present invention relates to electronic circuits, more specifically, the present invention relates to switching regulator, the control circuit and method thereof.

### BACKGROUND

Peak current mode control and constant on time mode control are two widely used control schemes in the power conversion field. In the peak current mode control, the output voltage is fed back to the feedback loop. An error amplified signal is generated by amplifying and integrating a difference between the output voltage and a voltage reference. Then the error amplified signal is compared to a current sense signal indicative of the inductor current to generate a PWM control signal which is used to control a power stage of the switching regulator. Thus, in the peak current mode control, the error amplified signal reflects the output current information (i.e. the load status). If the error amplified signal is very low (e.g. lower than a sleep reference), which indicates that the system is in light load condition, the system will enter sleep mode to improve efficiency. However, in the constant on time mode control, the inductor current information is not involved in the control loop, so the feedback signal does not reflect the load status. The feedback signal may be still larger than the sleep reference even in a very light load condition, which prevents the system from entering sleep mode, and leads to higher power loss.

### SUMMARY

It is an object of the present invention to provide an improved switching regulator, which solves the above problems.

In accomplishing the above and other objects, there has been provided, in accordance with an embodiment of the present invention, a switching regulator, comprising: a power stage, operable to convert an input voltage into an output voltage; a DCM detector, configured to generate a detect signal in response to a current flowing through the power stage; a timer, operable to start to time if the detect signal indicates the switching regulator is in discontinuous current mode, and to generate a timeout signal when timing out; a minimum on time circuit, configured to generate a minimum on time signal in response to the timeout signal; and a logic & drive circuit, configured to generate a drive signal in response to the timeout signal and the minimum on time signal, to control the operation of the power stage.

In addition, there has been provided, in accordance with an embodiment of the present invention, a control circuit used in a switching regulator, the switching regulator including a power stage configured to convert an input voltage to an output voltage, the control circuit comprising: a DCM detector, configured to generate a detect signal in response to a current flowing through the power stage; a timer, operable to start to time if the detect signal indicates the switching regulator is in discontinuous current mode, and to generate a timeout signal when timing out; a minimum on time circuit, configured to generate a minimum on time signal in response to the timeout signal; and a logic & drive circuit, configured to generate a drive signal in response to the timeout signal and the minimum on time signal, to control the operation of the power stage.

Furthermore, there has been provided, in accordance with an embodiment of the present invention, a method used in a switching regulator, the switching regulator including a power stage configured to convert an input voltage to an output voltage, the method comprising: detecting whether the switching regulator is in discontinuous current mode; starting to time a preset time duration if the detection indicates the switching regulation is in discontinuous current mode; and controlling the power stage to be ON for a minimum on time when timing out.

### BRIEF DESCRIPTION OF THE DRAWINGS

FIG. 1 schematically shows a switching regulator 100 in accordance with an embodiment of the present invention.

FIG. 2 schematically shows a switching regulator 200 in accordance with an embodiment of the present invention.

FIG. 3 schematically shows a switching regulator 300 in accordance with an embodiment of the present invention.

FIG. 4 schematically shows the waveforms of the error amplified signal V_{EA}, the sleep reference Vₛₗₑₑₚ, the inductor current I_{L}, the sleep signal SLEEP and the drive signal D_{G} in FIGS. 2 & 3 in accordance with an embodiment of the present invention.

FIG. 5 schematically shows a switching regulator 500 in accordance with an embodiment of the present invention.

FIG. 6 schematically shows a switching regulator 600 in accordance with an embodiment of the present invention.

FIG. 7 schematically shows a flowchart 700 of a method used in a switching regulator in accordance with an embodiment of the present invention.

The use of the similar reference label in different drawings indicates the same of like components.

### DETAILED DESCRIPTION

Embodiments of circuits for switching regulator with improved efficiency are described in detail herein. In the following description, some specific details, such as example circuits for these circuit components, are included to provide a thorough understanding of embodiments of the invention. One skilled in relevant art will recognize, however, that the invention can be practiced without one or more specific details, or with other methods, components, materials, etc.

The following embodiments and aspects are illustrated in conjunction with circuits and methods that are meant to be exemplary and illustrative. In various embodiments, the above problem has been reduced or eliminated, while other embodiments are directed to other improvements.

FIG. 1 schematically shows a switching regulator 100 in accordance with an embodiment of the present invention. In the example of FIG. 1, the switching regulator 100 comprises: a power stage 101 and a control circuit 120, the power stage 101 including a power switch periodically ON and OFF, to convert an input voltage V_{IN} into an output voltage V_{O}; the control circuit 120 comprising: a DCM detector 102, configured to receive a current sensing signal I_{S} indicative of a current flowing through the power stage 101, to generate a detect signal DCM, the detect signal DCM indicating whether the switching regulator 100 is in discontinuous current mode; a timer 103, operable to start to time if the detect signal DCM indicates the switching regulator 100 is in discontinuous current mode, and to generate a timeout signal T when the timer 103 times out; a minimum on time circuit 104, configured to generate a minimum on time signal (min-on) in response to the timeout signal T; and a logic & drive circuit 105, configured to generate a drive signal D_{G} in response to the timeout signal T and the minimum on time signal (min-on), to control the operation of the power stage 101.

In one embodiment, the power stage 101 is controlled to be ON for a minimum on time duration when the switching regulator is in discontinuous current mode: the logic & drive circuit 105 is configured to turn on the power stage 101 in response to the timeout signal T, and configured to turn off the power stage 101 in response to the minimum on time signal (min-on) after the power stage 101 has been ON for the minimum on time duration.

In real applications, the switching regulator comprises an energy storage component (e.g. an inductor), and the current flowing through the power stage is the same current flowing through the energy storage component, which is typically indicated as the inductor current I_{L}, as will be shown later in FIG. 4. Thus, the current sense signal I_{S} also represents the inductor current I_{L}. The DCM detector 102 compares the current sense signal I_{S} with a zero reference voltage (e.g. 0.1V) to detect whether the system is in discontinuous current mode.

In one embodiment, the timer 103 starts to time in response to the detection of the DCM detector 102. The timer 103 is reset when the previous timing is over, and restarts to time when an update detection indicating the system is in discontinuous current mode again.

If the status of the switching regulator in discontinuous current mode lasted for a preset time duration, the power stage is controlled to be ON for a minimum on time duration. The current flowing through the power stage 101 (i.e. the inductor current) starts to rise during this minimum on time period, and starts to fall after the minimum on time period. When the current flowing through the power stage 101 falls to zero, the system enters discontinuous current mode again. If the system has not entered sleep mode yet, the timer 103 would time again; and the power stage 101 will be ON for the minimum on time duration again after the timer 103 times out. This process repeats: the power stage 101 is ON for the minimum on time when the discontinuous current mode lasts for the preset time duration in each switching cycle, so that a corresponding signal will finally reach the sleep reference, causing the system to successfully enter sleep mode. Accordingly, most of the circuits (e.g. the timer 103, the minimum on time circuit 104, the power stage 101, etc.) are disabled, which reduces the power loss and improves the efficiency. When the system enters sleep mode, the timer 103 will not time; and the power stage 101 will not be turned on until the system exits sleep mode.

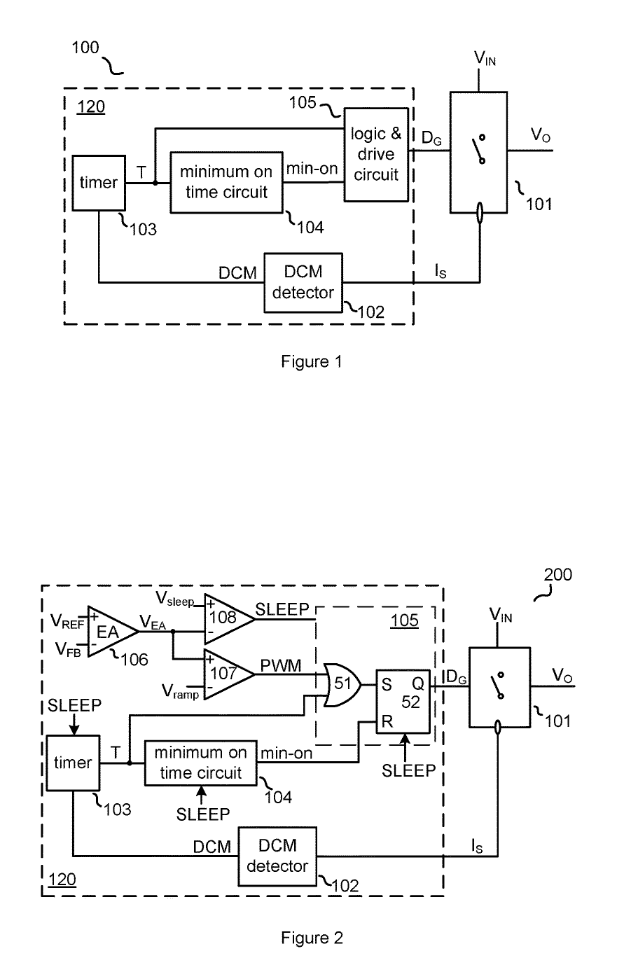

FIG. 2 schematically shows a switching regulator 200 in accordance with an embodiment of the present invention. In the example of FIG. 2, the control circuit 120 comprises: the DCM detector 102, the timer 103, the minimum on time circuit 104 and the logic & drive circuit 105 as in FIG. 1, and the control circuit 120 further comprises: an error amplifier (EA) 106, configured to receive a voltage reference V_{REF} and a feedback signal V_{FB} indicative of the output voltage V_{O}, to generate an error amplified signal V_{EA} by amplifying and integrating a difference between the feedback signal V_{FB} and the voltage reference V_{REF}; a voltage comparator 107, configured to receive the error amplified signal V_{EA} and a ramp signal Vᵣₐₘₚ, and to generate a comparison signal PWM by comparing the error amplified signal V_{EA} with the ramp signal Vᵣₐₘₚ; and a sleep comparator 108, configured to receive the error amplified signal V_{EA} and a sleep reference Vₛₗₑₑₚ, and to generate a sleep signal SLEEP by comparing the error amplified signal V_{EA} with the sleep reference Vₛₗₑₑₚ, the sleep signal SLEEP operable to indicate whether the switching regulator enters sleep mode. The comparison signal PWM, the sleep signal SLEEP and the minimum on time signal (min-on) are configured to control the power stage 101 by way of the logic & drive circuit 105.

FIG. 2 also schematically shows a circuit configuration of the logic & drive circuit 105 in accordance with an embodiment of the present invention. In the example FIG. 2, the logic & drive circuit 105 comprises: a logical OR circuit (i.e. a first logical OR unit) 51, configured to receive the comparison signal PWM and the timeout signal T, to generate a set signal by executing OR operation on the comparison signal PWM and the timeout signal T; and a RS flip-flop 52, having a set input terminal S, a reset input terminal R and an output terminal Q, wherein the set input terminal S is configured to receive the set signal, the reset input terminal R is configured to receive the minimum on time signal (min-on), and the RS flip-flop 52 is configured to generate the drive signal D_{G} in response to the set signal and the minimum on time signal (min-on), to control the operation of the power stage 101.

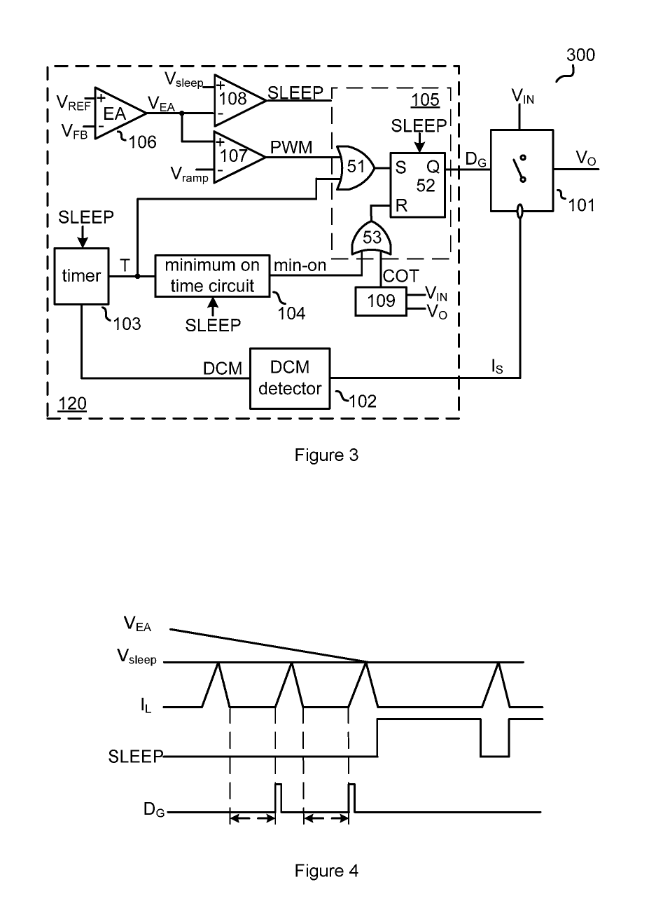

FIG. 3 schematically shows a switching regulator 300 in accordance with an embodiment of the present invention. The switching regulator 300 in FIG. 3 is similar to the switching regulator 200 in FIG. 2, with a difference that in the example of FIG. 3, the control circuit 120 of the switching regulator 300 further comprises: a constant on time circuit 109, configured to receive the input voltage V_{IN} and the output voltage V_{O}, to generate a constant on time signal COT to the logic & drive circuit 105, to control the operation of the power stage 101. The logic & drive circuit 105 further comprises: a logical OR circuit (i.e. a second logical OR unit) 53, configured to receive the minimum on time signal (min-on) and the constant on time signal COT, to generate a reset signal by executing OR operation on the minimum on time signal (min-on) and the constant on time signal COT, wherein the reset signal is then delivered to the reset input terminal of the RS flip-flop 52, to control the on time duration of the power stage 101.

When the switching regulators 200 and 300 are in operation, the feedback signal V_{FB} is delivered to the error amplifier 106 to generate the error amplified signal V_{EA}. If the load is in normal condition (e.g. the load current is inside a set range), the error amplified signal V_{EA} is higher than the sleep reference Vₛₗₑₑₚ, so the sleep signal SLEEP indicates that the system operates normally. If the inductor current is in CCM (continuous current mode), the detection of the DCM detector 102 would indicate that the system is not in discontinuous current mode. Accordingly, the timer 103 would not start to time, and the minimum on time circuit 104 takes no action. When the power stage 101 is turned off, the output voltage V_{O} (i.e. the feedback signal V_{FB}) decreases, and the error amplified signal V_{EA} increases. When the error amplified signal V_{EA} increases to the ramp signal Vᵣₐₘₚ, the comparison signal PWM turns to high, which sets the drive signal D_{G} by way of the logical OR circuit 51. As a result, the power stage 101 is turned on. At the same time, the constant on time circuit 109 outputs the constant on time signal COT, so as to turn off the power stage 101 after the power stage 101 has been ON for a fixed on time period. Above process repeats, so as to regulate the output voltage V_{O} to the desired voltage level.

If the load starts to decrease, causing the system to enter discontinuous current mode, the DCM detector 102 outputs the detect signal DCM to the timer 103. Then the timer 103 starts to time. When the discontinuous current mode condition lasted for the preset time duration, the power stage 101 is controlled to be ON for the minimum on time duration. During this minimum on time period, the inductor current rises until this time period ends. Then the inductor current starts to fall. When the inductor current falls to zero, the system enters discontinuous current mode again. If the error amplified signal V_{EA} is still higher than the sleep reference Vₛₗₑₑₚ at this time point, the system will not enter sleep mode. So the power stage 101 would be again turned on for the minimum on time duration. The process repeats until the error amplified signal V_{EA} goes lower than the sleep reference Vₛₗₑₑₚ. Then the sleep comparator 108 generates the sleep signal SLEEP to indicate the system enters sleep mode.

FIG. 4 schematically shows the waveforms of the error amplified signal V_{EA}, the sleep reference V_{sleep,} the inductor current I_{L}, the sleep signal SLEEP and the drive signal D_{G} in FIGS. 2 & 3 in accordance with an embodiment of the present invention. As shown in FIG. 4, the error amplified signal V_{EA} has decreased to the sleep reference Vₛₗₑₑₚ when the power stage 101 is ON for the minimum on time for successive two switching cycles. As a result, the sleep signal SLEEP jumps to high, which ensures the system enters sleep mode successfully. Accordingly, most of the circuits are disabled, the power loss is reduced and the efficiency is improved.

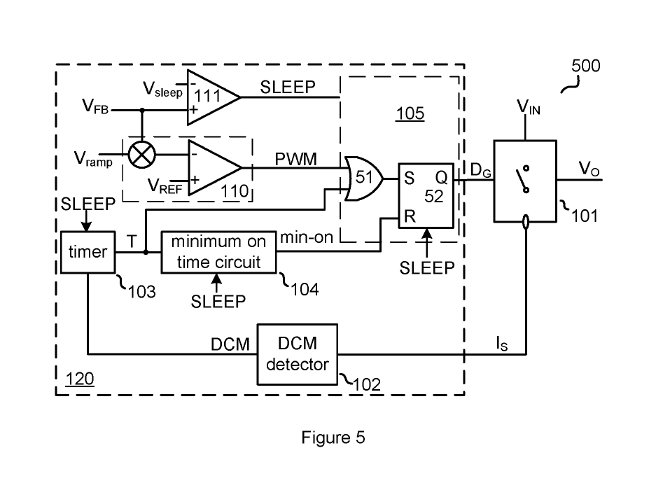

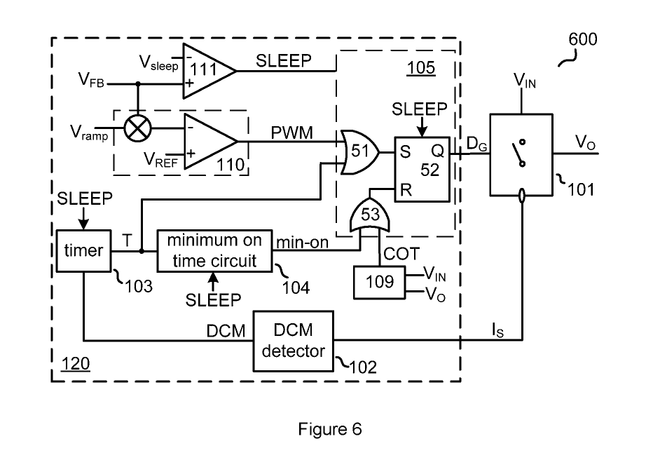

In the examples of FIG. 2 and FIG. 3, the feedback signal V_{FB} is first converted to the error amplified signal V_{EA}, and then the error amplified signal V_{EA} is compared to the sleep reference Vₛₗₑₑₚ (the sleep reference would have a relatively low value in such case), to detect whether the system is in discontinuous current mode and whether the system enters sleep mode. However, one skilled in the art should realize that the feedback loop may contain no error amplifier, and the feedback signal V_{FB} may be compared to the sleep reference Vₛₗₑₑₚ directly (the sleep reference would have a relatively high value in such case), to detect whether the system is in discontinuous current mode and whether the system enters sleep mode, which will be further discussed in the examples of FIG. 5 and FIG. 6.

FIG. 5 schematically shows a switching regulator 500 in accordance with an embodiment of the present invention. In the example of FIG. 5, the control circuit 120 comprises: the DCM detector 102, the timer 103, the minimum on time circuit 104 and the logic & drive circuit 105 as in FIG. 1, and the control circuit 120 further comprises: a voltage comparator 110, configured to receive a feedback signal V_{FB} indicative of the output voltage V_{O}, a voltage reference V_{REF} and a ramp signal Vᵣₐₘₚ, to generate a comparison signal PWM by comparing a sum of the feedback signal V_{FB} and the ramp signal Vᵣₐₘₚ with the voltage reference V_{REF}; and a sleep comparator 111, configured to receive the feedback signal V_{FB} and a sleep reference Vₛₗₑₑₚ, to generate a sleep signal SLEEP by comparing the feedback signal V_{FB} with the sleep reference Vₛₗₑₑₚ. The comparison signal PWM, the sleep signal SLEEP and the minimum on time signal (min-on) are operable to control the power stage 101 by way of the logic & drive circuit 105, to convert the input voltage to the output voltage.

FIG. 6 schematically shows a switching regulator 600 in accordance with an embodiment of the present invention. The switching regulator 600 in FIG. 6 is similar to the switching regulator 500 in FIG. 5, with a difference that in the example of FIG. 6, the control circuit 120 of the switching regulator 600 further comprises: a constant on time circuit 109, configured to receive the input voltage V_{IN} and the output voltage V_{O}, to generate a constant on time signal COT to the logic & drive circuit 105, and to control the operation of the power stage 101. The logic & drive circuit 105 further comprises: a logical OR circuit (i.e. a second logical OR unit) 53, configured to receive the minimum on time signal (min-on) and the constant on time signal COT, to generate a reset signal by executing OR operation on the minimum on time signal (min-on) and the constant on time signal COT, wherein the reset signal is then delivered to the reset input terminal of the RS flip-flop 52, to control the on time duration of the power stage 101.

When the switching regulators 500 and 600 are in operation, the feedback signal V_{FB} is directly compared with the sleep reference Vₛₗₑₑₚ and the voltage reference V_{REF}. If the load is in normal condition, the feedback signal V_{FB} is lower than the sleep reference Vₛₗₑₑₚ, so the sleep signal SLEEP indicates that the system operates normally. If the inductor current is in CCM, the detection of the DCM detector 102 would indicate that the system is not in discontinuous current mode. Accordingly, the timer 103 would not start to time, and the minimum on time circuit 104 takes no action. When the power stage 101 is turned off, the output voltage V_{O} (i.e. the feedback signal V_{FB}) decreases. When the sum of the feedback signal V_{FB} and the ramp signal Vᵣₐₘₚ decreases to the voltage reference V_{REF}, the comparison signal PWM turns to high, which sets the drive signal D_{G} by way of the logical OR circuit 51. As a result, the power stage 101 is turned on. At the same time, the constant on time circuit 109 outputs the constant on time signal COT, so as to turn off the power stage 101 after the power stage 101 is ON for a fixed on time period. Above process repeats, so as to regulate the output voltage V_{O} to the desired voltage level.

If the load starts to decrease, causing the system to enter discontinuous current mode, the DCM detector 102 outputs the detect signal DCM to the timer 103. Then the timer 103 starts to time. When the discontinuous current mode lasts for the preset time duration, the power stage 101 is controlled to be ON for the minimum on time duration. During this minimum on time period, the inductor current rises until this time period ends. Then the inductor current starts to fall. When the inductor current falls to zero, the system enters discontinuous current mode again. If the feedback signal V_{FB} is still lower than the sleep reference Vₛₗₑₑₚ at this time point, the system will not enter sleep mode. So the power stage 101 would be again turned on for the minimum on time duration. The process repeats until the feedback signal V_{FB} goes higher than the sleep reference Vₛₗₑₑₚ. Then the sleep comparator 111 generates the sleep signal SLEEP to indicate the system enters sleep mode. Accordingly, most of the circuits are disabled, the power loss is reduced and the efficiency is improved.

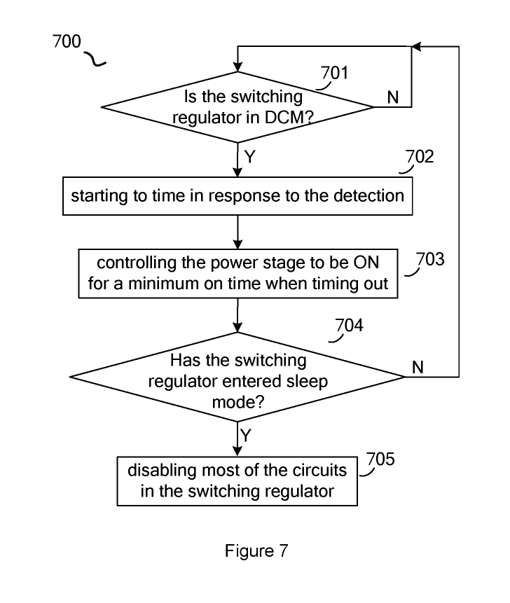

FIG. 7 schematically shows a flowchart 700 of a method used in a switching regulator in accordance with an embodiment of the present invention. The switching regulator including a power stage configured to convert an input voltage to an output voltage, the method comprises:

Step 701, detecting whether the switching regulator is in DCM (discontinuous current mode), if the detection indicates the switching regulator is in DCM, going to step 702, if not, continuing detecting whether the switching regulator is in DCM.

Step 702, starting to time a preset time duration in response to the detection. And

Step 703, controlling the power stage to be ON for a minimum on time when timing out.

In one embodiment, the method further comprising: step 704, detecting whether the switching regulator has entered sleep mode: if the switching regulator has entered sleep mode, going to step 705; if not, going back to step 701: continuing detecting whether the switching regulator is in DCM. And

Step 705, disabling most of the circuits in the switching regulator.

In one embodiment, the step detecting whether the switching regulator has entered sleep mode comprises: comparing a feedback signal indicative of the output voltage with a sleep reference.

In one embodiment, the step detecting whether the switching regulator has entered sleep mode comprises: generating an error amplified signal by amplifying and integrating a difference between a feedback signal indicative of the output voltage and a voltage reference; and comparing the error amplified signal with a sleep reference.

Several embodiments of the foregoing switching regulator provide improved efficiency compared to conventional technique discussed above. Unlike the conventional technique, several embodiments of the foregoing switching regulator monitor a current flowing through the power stage to detect whether the system is in discontinuous current mode. If the system is in discontinuous current mode, the power stage is controlled to be ON for a minimum on time duration in each switching cycle until the system enters sleep mode. So several embodiments of the foregoing switching regulator ensure the system successfully enters sleep mode even adopting constant on time control.

It is to be understood in these letters patent that the meaning of “A” is coupled to “B” is that either A and B are connected to each other as described below, or that, although A and B may not be connected to each other as described above, there is nevertheless a device or circuit that is connected to both A and B. This device or circuit may include active or passive circuit elements, where the passive circuit elements may be distributed or lumped-parameter in nature. For example, A may be connected to a circuit element that in turn is connected to B.

This written description uses examples to disclose the invention, including the best mode, and also to enable a person skilled in the art to make and use the invention. The patentable scope of the invention may include other examples that occur to those skilled in the art.

What is claimed is:

1. A switching regulator, comprising:
a power stage, operable to convert an input voltage into an output voltage;
a DCM detector, configured to generate a detect signal in response to a current flowing through the power stage;
a timer, operable to start to time if the detect signal indicates the switching regulator is in discontinuous current mode, and to generate a timeout signal when timing out;
a minimum on time circuit, configured to generate a minimum on time signal in response to the timeout signal; and
a logic & drive circuit, configured to generate a drive signal in response to the timeout signal and the minimum on time signal, to control the operation of the power stage.

2. The switching regulator of claim 1, wherein the power stage is controlled to be ON for a minimum on time duration when the switching regulator is in discontinuous current mode.

3. The switching regulator of claim 1, further comprising:
an error amplifier, configured to generate an error amplified signal in response to a voltage reference and a feedback signal indicative of the output voltage;
a voltage comparator, configured to generate a comparison signal by comparing the error amplified signal with a ramp signal; and
a sleep comparator, configured to generate a sleep signal by comparing the error amplified signal with a sleep reference, the sleep signal being operable to indicate whether the switching regulator enters sleep mode.

4. The switching regulator of claim 3, wherein the logic & drive circuit comprises:
a logical OR circuit, configured to generate a set signal by executing OR operation on the comparison signal and the timeout signal; and
a RS flip-flop, configured to generate the drive signal in response to the set signal and the minimum on time signal.

5. The switching regulator of claim 1, further comprising:
a constant on time circuit, configured to receive the input voltage and the output voltage, to generate a constant on time signal to the logic & drive circuit, to control the operation of the power stage.

6. The switching regulator of claim 1, further comprising:
a voltage comparator, configured to generate a comparison signal by comparing a sum of a feedback signal and a ramp signal with a voltage reference, the feedback signal being indicative of the output voltage; and
a sleep comparator, configured to generate a sleep signal by comparing the feedback signal with a sleep reference.

7. The switching regulator of claim 6, wherein the logic & drive circuit comprises:
a logical OR circuit, configured to generate a set signal by executing OR operation on the comparison signal and the timeout signal; and
a RS flip-flop, configured to generate the drive signal in response to the set signal and the minimum on time signal.

8. A control circuit used in a switching regulator, the switching regulator including a power stage configured to convert an input voltage to an output voltage, the control circuit comprising:
a DCM detector, configured to generate a detect signal in response to a current flowing through the power stage;
a timer, operable to start to time if the detect signal indicates the switching regulator is in discontinuous current mode, and to generate a timeout signal when timing out;
a minimum on time circuit, configured to generate a minimum on time signal in response to the timeout signal; and
a logic & drive circuit, configured to generate a drive signal in response to the timeout signal and the minimum on time signal, to control the operation of the power stage.

9. The control circuit of claim 8, wherein the logic & drive circuit is configured to turn on the power stage in response to the timeout signal, and is configured to turn off the power stage in response to the minimum on time signal after the power stage has been ON for a minimum on time duration.

10. The control circuit of claim 8, further comprising:
an error amplifier, configured to generate an error amplified signal in response to a voltage reference and a feedback signal indicative of the output voltage;
a voltage comparator, configured to generate a comparison signal by comparing the error amplified signal with a ramp signal; and
a sleep comparator, configured to generate a sleep signal by comparing the error amplified signal with a sleep reference, the sleep signal being operable to indicate whether the switching regulator enters sleep mode.

11. The control circuit of claim 10, wherein the logic & drive circuit comprises:
a logical OR circuit, configured to generate a set signal by executing OR operation on the comparison signal and the timeout signal; and
a RS flip-flop, configured to generate the drive signal in response to the set signal and the minimum on time signal.

12. The control circuit of claim 8, further comprising:
a constant on time circuit, configured to receive the input voltage and the output voltage, to generate a constant on time signal to the logic & drive circuit, to control the operation of the power stage.

13. The control circuit of claim 8, further comprising:
a voltage comparator, configured to generate a comparison signal by comparing a sum of a feedback signal and a ramp signal with a voltage reference, the feedback signal being indicative of the output voltage; and
a sleep comparator, configured to generate a sleep signal by comparing the feedback signal with a sleep reference.

14. The control circuit of claim 13, wherein the logic & drive circuit comprises:
a logical OR circuit, configured to generate a set signal by executing OR operation on the comparison signal and the timeout signal; and
a RS flip-flop, configured to generate the drive signal in response to the set signal and the minimum on time signal.

15. A method used in a switching regulator, the switching regulator including a power stage configured to convert an input voltage to an output voltage, the method comprising:
detecting whether the switching regulator is in discontinuous current mode;
starting to time a preset time duration if the detection indicates the switching regulation is in discontinuous current mode; and
controlling the power stage to be ON for a minimum on time when timing out.

16. The method of claim 15, further comprising:
detecting whether the switching regulator has entered sleep mode: if the switching regulator has entered sleep mode, disabling most of the circuits in the switching regulator; if not, continuing detecting whether the switching regulator is in discontinuous current mode.

17. The switching regulator of claim 15, wherein the step detecting whether the switching regulator has entered sleep mode comprises:
comparing a feedback signal indicative of the output voltage with a sleep reference.

18. The switching regulator of claim 15, wherein the step detecting whether the switching regulator has entered sleep mode comprises:
generating an error amplified signal by amplifying and integrating a difference between a feedback signal indicative of the output voltage and a voltage reference; and
comparing the error amplified signal with a sleep reference.
